(19) United States
(12) Patent Application Publication
(10) Pub. No.: US 2022/0334081 A1
(43) Pub. Date: Oct. 20, 2022

(54) APPARATUS FOR MEASURING AT LEAST ONE ELECTROMAGNETIC PROPERTY OF A SAMPLE OF MATERIAL

(71) Applicant: ROGERS CORPORATION, Chandler, AZ (US)

(72) Inventors: Gianni Taraschi, Arlington, MA (US); Kristi Pance, Auburndale, MA (US)

(21) Appl. No.: 17/855,473

(22) Filed: Jun. 30, 2022

(51) Int. Cl. G01N 27/72

(52) U.S. Cl. CPC G01N 27/72

(57) ABSTRACT

An apparatus for measuring an electromagnetic property of a material sample, includes: a housing having an internal cavity and a removable cover, wherein the housing with cover forms an electromagnetic resonance chamber; a container configured to receive the material sample, wherein the container extends along a y-axis of the housing through opposing sidewalls of the housing and passes through an x-y-z center point of the cavity; two opposing electrical signal lines oriented along an x-axis of the housing are disposed and configured to couple to an electromagnetic resonant mode of the cavity; at least one resonator concentrically disposed about the container and disposed within the cavity, wherein the at least one resonator is fixed or fixedly movable relative to the y-axis; and, a frequency tuner concentrically disposed about the container and at least partially disposed within the cavity, wherein the frequency tuner is fixedly movable along the y-axis.

### BACKGROUND

The present disclosure relates generally to an apparatus for measuring at least one electromagnetic property of a sample of material, particularly to an apparatus for measuring at least one of a magnetic property and a dielectric property of a sample of material, and more particularly to an apparatus for measuring a magnetic property and a dielectric property of the same sample of material.

Existing apparatuses for measuring at least one electromagnetic property of a sample of material include, for example: a coaxial probe; a transmission line; a transmitter and receiver in free space; a resonant cavity; a parallel plate; and, a toroidal inductor.

While existing apparatuses for measuring electromagnetic properties of a sample of material may be suitable for their intended purpose, the art of measuring multiple electromagnetic properties of a sample of material, and particularly of measuring both magnetic and dielectric material properties of a sample of material, would be advanced with an apparatus that can be used for measuring both magnetic and dielectric properties of the same sample of material.

### BRIEF SUMMARY

An embodiment includes an apparatus for measuring at least one electromagnetic property of a sample of material as defined by the appended independent claim(s). Further advantageous modifications of the an apparatus for measuring at least one electromagnetic property of a sample of material are defined by the appended dependent claims.

In an embodiment, an apparatus for measuring at least one electromagnetic property of a sample of material, includes: a housing having an internal cavity and a removable cover, wherein the combination of the housing with the cover attached forms an electromagnetic resonance chamber; a container configured to receive the sample of material, wherein the container extends along a y-axis of the housing through opposing sidewalls of the housing and passes through an x-y-z center point of the cavity; two opposing electrical signal lines oriented along an x-axis of the housing that are disposed and configured to couple to an electromagnetic resonant mode of the cavity; at least one resonator concentrically disposed about the container and disposed within the cavity, wherein the at least one resonator is fixed or fixedly movable relative to the y-axis; and, a frequency tuner concentrically disposed about the container and at least partially disposed within the cavity between the at least one resonator and one of the sidewalls of the housing, wherein the frequency tuner is fixedly movable along the y-axis.

In an embodiment, a method of measuring magnetic properties of a sample of material, includes, while using the foregoing described apparatus: inserting the particular sample of material into the container until it is disposed fully inside the cavity in the container; energizing the two opposing electrical signal lines with a particular frequency to cause the first and second dielectric resonator pucks to resonate; while monitoring signal feedback on the two opposing electrical signal lines via a network analyzer, adjusting along the y-axis the gap between the first and second dielectric resonator pucks to obtain a coarse tuning adjustment, and adjusting along the y-axis the frequency tuner to obtain a fine tuning adjustment, wherein the coarse and fine tuning adjustments result in the first and second resonator pucks, and the particular sample, resonating in a TE mode at the resonant mode of the cavity; and, measuring at least one of the permeability and the magnetic loss tangent of the particular sample via the signal feedback and the network analyzer.

In an embodiment, a method of measuring electric properties of a sample of material, includes, while using the foregoing described apparatus: inserting the particular sample of material into the container until it is disposed fully inside the cavity in the container; energizing the two opposing electrical signal lines with a particular frequency; while monitoring signal feedback on the two opposing electrical signal lines via a network analyzer, adjusting along the y-axis a frequency tuned condition, by adjusting along the y-axis the position of the at least one resonator, that results in the at least one resonator, and the particular sample, resonating in a TM mode at the resonant mode of the cavity; and, measuring at least one of the permittivity and the dielectric loss tangent of the particular sample via the signal feedback and the network analyzer.

The above features and advantages and other features and advantages of the invention are readily apparent from the following detailed description of the invention when taken in connection with the accompanying drawings.

### BRIEF DESCRIPTION OF THE DRAWINGS

Referring to the exemplary non-limiting drawings wherein like elements are numbered alike, or illustrated alike, in the accompanying Figures:

FIG. 1 depicts a top-down plan view of a first portion of an apparatus for measuring a permeability, μ, and a magnetic loss tangent, δμ, via a transverse electric, TE, mode of a sample of material, in accordance with an embodiment;

FIG. 2 depicts a top-down plan view of a second portion of an apparatus for measuring a permittivity, ε, and a dielectric loss tangent, δε, via a transverse magnetic, TM, mode of the sample of material of FIG. 1, in accordance with an embodiment;

FIGS. 3A, 3B, 3C, 3D, 3E, 3F, 3G, 3H, and 3I, depict, in sequence, assembly steps of an example construct of the first portion of FIG. 1, in accordance with an embodiment; and

FIGS. 4A, 4B, and 4C, depict analytical electromagnetic performance characteristics of: the first portion depicted in FIG. 4A configured to resonate in TE mode with E-field intensity plotted; and, the second portion depicted in FIG. 4C configured to resonate in TM mode with H-field intensity plotted; and, where FIG. 4B depicts the reconfigurable resonator response depicted in FIG. 4A with and without a test sample of material in situ, in accordance with an embodiment.

One skilled in the art will understand that the drawings, further described herein below, are for illustration purposes only. It will be appreciated that for simplicity and clarity of illustration, elements shown in the figures have not necessarily been drawn to scale. For example, the dimensions or scale of some of the elements may be exaggerated relative to other elements for clarity. Further, where considered appropriate, reference numerals may be repeated among the figures to indicate corresponding or analogous elements, or analogous elements may not be repetitively enumerated in all figures where it will be appreciated and understood that such enumeration where absent is inherently disclosed.

### DETAILED DESCRIPTION

As used herein, the phrase “embodiment” means “embodiment disclosed and/or illustrated herein”, which may not necessarily encompass a specific embodiment of an invention in accordance with the appended claims, but nonetheless is provided herein as being useful for a complete understanding of an invention in accordance with the appended claims.

Although the following detailed description contains many specifics for the purposes of illustration, anyone of ordinary skill in the art will appreciate that many variations and alterations to the following details are within the scope of the appended claims. For example, where described features may not be mutually exclusive of and with respect to other described features, such combinations of non-mutually exclusive features are considered to be inherently disclosed herein. Additionally, common features may be commonly illustrated in the various figures but may not be specifically enumerated in all figures for simplicity, but would be recognized by one skilled in the art as being an explicitly disclosed feature even though it may not be enumerated in a particular figure. Accordingly, the following example embodiments are set forth without any loss of generality to, and without imposing limitations upon, the claimed invention disclosed herein.

Two resonant-based measurement systems are proposed that enable the measurement of permeability, permittivity, and their respective loss tangent. The two resonant-based measurement systems may employ the same sample of material, thereby eliminating potential error due to differences when using different samples to measure the permeability and permittivity of a sample of material.

A first measurement system is a resonant-based measurement system, which is employed to implement a method to measure permeability and loss tangent.

The first system to measure permeability and the respective loss tangent of the permeability includes a plurality of high-dielectric constant “pucks”, which form a reconfigurable resonator that operates in its fundamental TE mode. The system is tuned to the desired frequency of measurement using a turner assembly that adjusts the relative distance between the pucks. A low-dielectric constant shaft with a hole in the center allows for a sample to be inserted, which in turn shifts the resonant frequency of the system. The frequency shift is measured using a vector network analyzer (VNA) and is proportional to the permeability of the inserted sample. In addition, the 3 dB bandwidth of the response curve (Q) is also measured using the VNA and is proportional to the loss tangent of the permeability of the inserted sample. Electromagnetic simulations are used to calibrate the scaling relations between the above-mentioned measurement values and the sample material permeability and loss tangent of the permeability, which depend on the specifics of the resonator assembly, the metal cavity, and the coupling loops to the system.

Example steps to measure include:

Using the tuner, tune the empty cavity to the desired measurement frequency, as measured using a VNA coupled to the coupling loops.

Insert the sample.

Measure the resonant frequency shift and the Q of the response curve, as measured using a VNA.

Remove the sample and measure the cross-section dimensions of the sample.

Input the measured frequency shift and the cross-section dimensions of the sample into the calibrated scaling relations to calculate the permeability.

Input the measured Q and the cross-section dimensions of the sample into the calibrated scaling relations to calculate the loss tangent of the permeability.

A second measurement system is a resonant-based measurement system, which is employed to implement a method to measure the permittivity and loss tangent of a sample of material.

The second system to measure permittivity and the respective loss tangent of the permittivity includes a resonator, formed of metal or high-dielectric constant material, which forms a reconfigurable resonator that operates in its fundamental TM mode. The system is tuned to the desired frequency of measurement using a turner assembly that adjusts the relative distance between the resonator and a metal surface of the turner within the metal cavity. A hole in the center of the tuner and the resonator allows for a sample to be inserted, which in turn shifts the resonant frequency of the system. The frequency shift is measured using a vector network analyzer (VNA) and is proportional to the permittivity of the inserted sample. In addition, the 3dB bandwidth of the response curve (Q) is also measured using the VNA and is proportional to the loss tangent of the permittivity of the inserted sample. Electromagnetic simulations are used to calibrate the scaling relations between the above-mentioned measurement values and the sample material permittivity and loss tangent of the permittivity, which depend on the specifics of the resonator assembly, the metal cavity, and the coupling loops to the system.

Example steps to measure include:

Using the tuner, tune the empty cavity to the desired measurement frequency, as measured using a VNA coupled to the coupling loops.

Insert the sample.

Measure the resonant frequency shift and the Q of the response curve, as measured using a VNA.

Remove the sample and measure the cross-section dimensions of the sample.

Input the measured frequency shift and the cross-section dimensions of the sample into the calibrated scaling relations to calculate the permittivity.

Input the measured Q and the cross-section dimensions of the sample into the calibrated scaling relations to calculate the loss tangent of the permittivity.

An embodiment, as shown and described by the various figures and accompanying text, provides an apparatus for measuring electromagnetic properties, particularly permeability and permittivity properties, of a same sample of a material. It is of significance to note that the same sample of a material may be used for both permeability and permittivity measurements, which greatly improves the accuracy of the measurement, as subtle differences, in material properties or physical properties that could affect material properties, between one sample of material to another sample of material can be negated. The sample of material may be a solid, a powder, or a liquid.

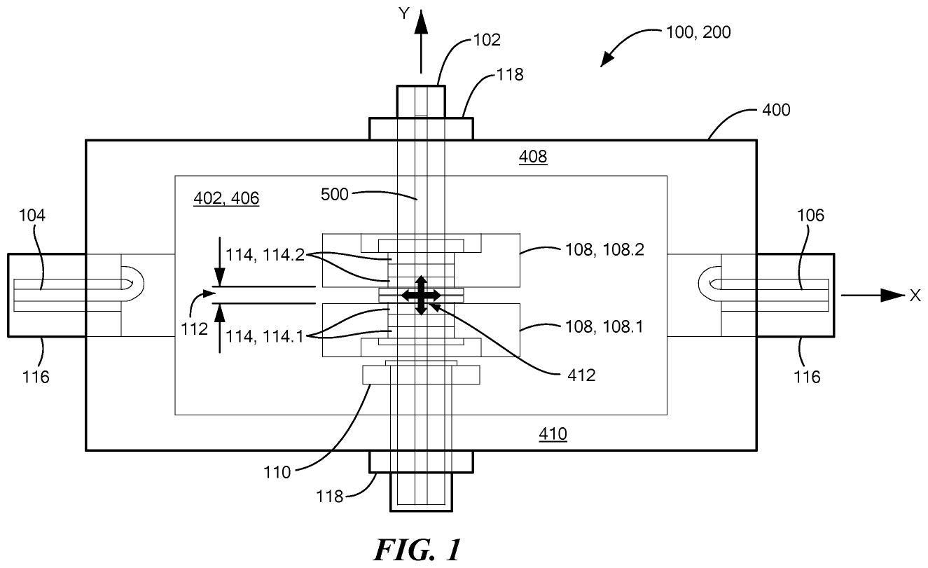

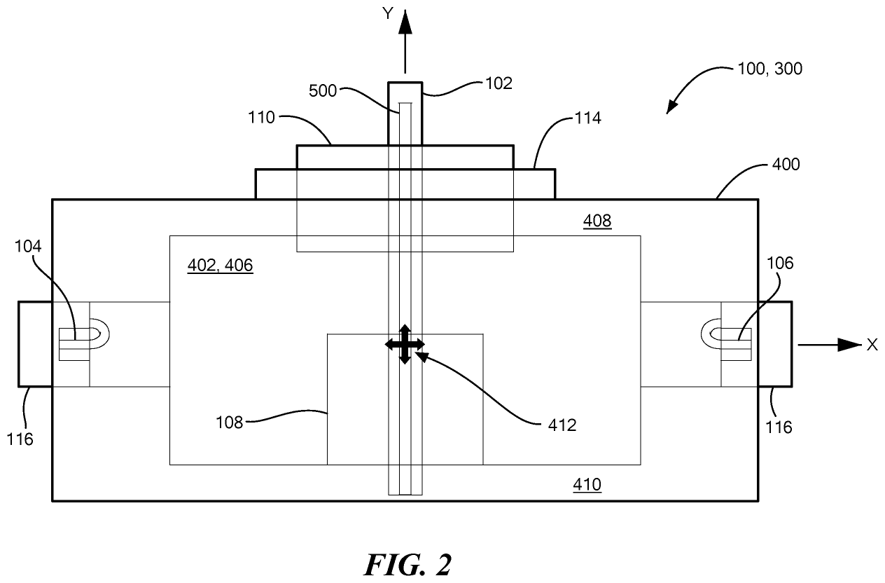

In an embodiment, and with reference to FIGS. 1 and 2 collectively, an apparatus 100 (first portion 200 and second portion 300 illustrated separately, as they may be employed separate of one another, employed together as separate units, or employed together as a combined unit) for measuring at least one electromagnetic property of a sample of material 500 is disclosed, wherein: the first portion 200 (see FIG. 1) is useful for measuring a magnetic property, such as permeability, μ, and a magnetic loss tangent, δμ, of the sample of material 500 via a transverse electric, TE, mode; and, the second portion 300 (see FIG. 2) is useful for measuring an electrical property, such as a permittivity, ε, and a dielectric loss tangent, δε, of the sample of material 500, as depicted in FIG. 1, via a transverse magnetic, TM, mode.

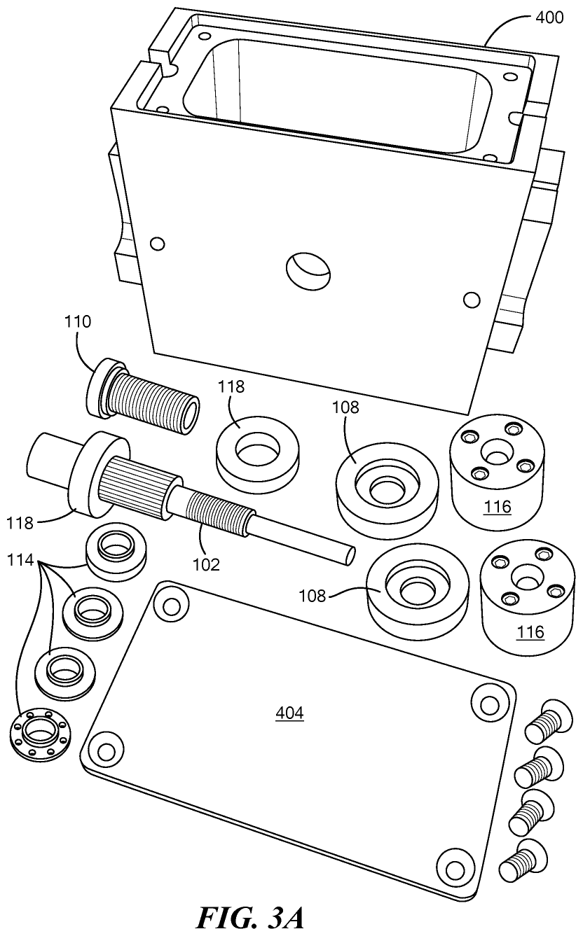

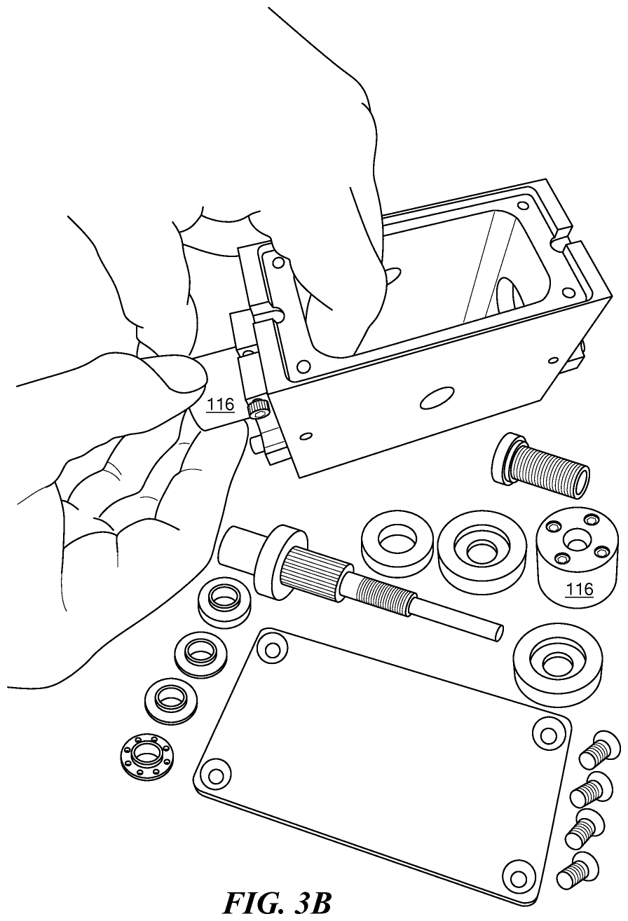

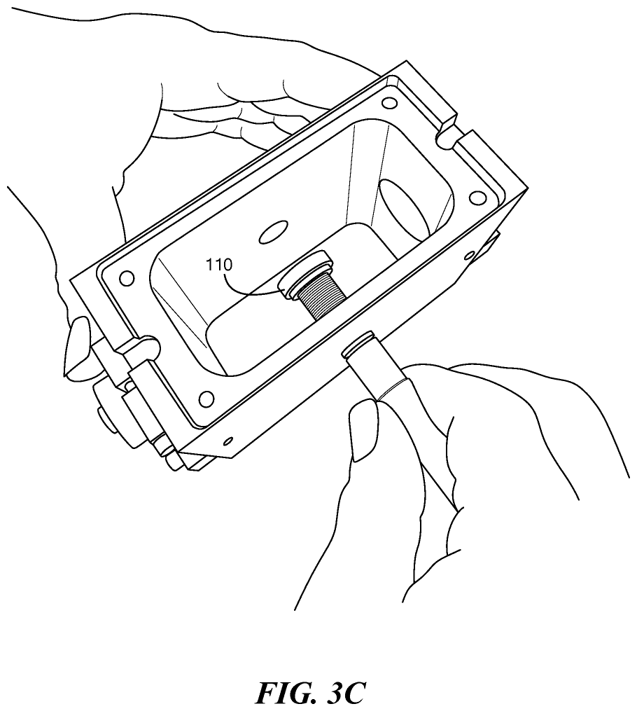

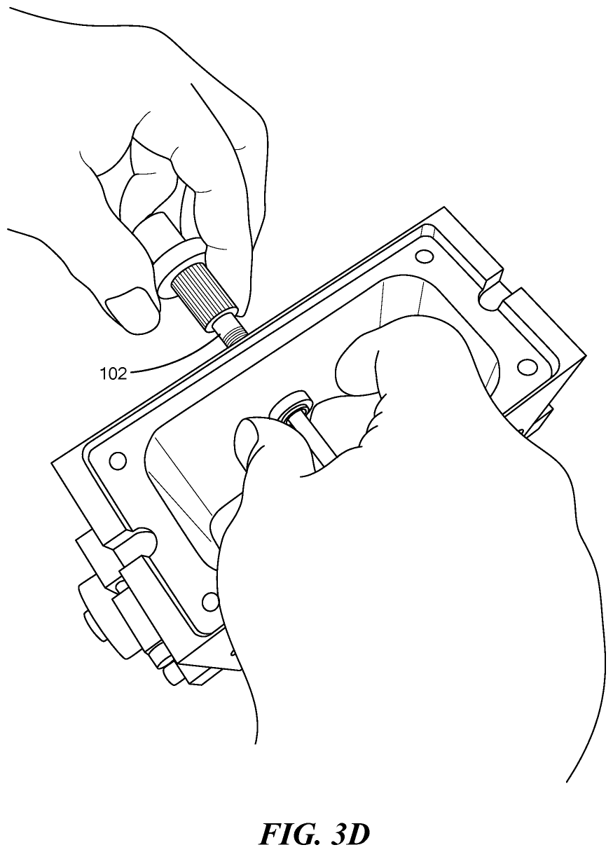

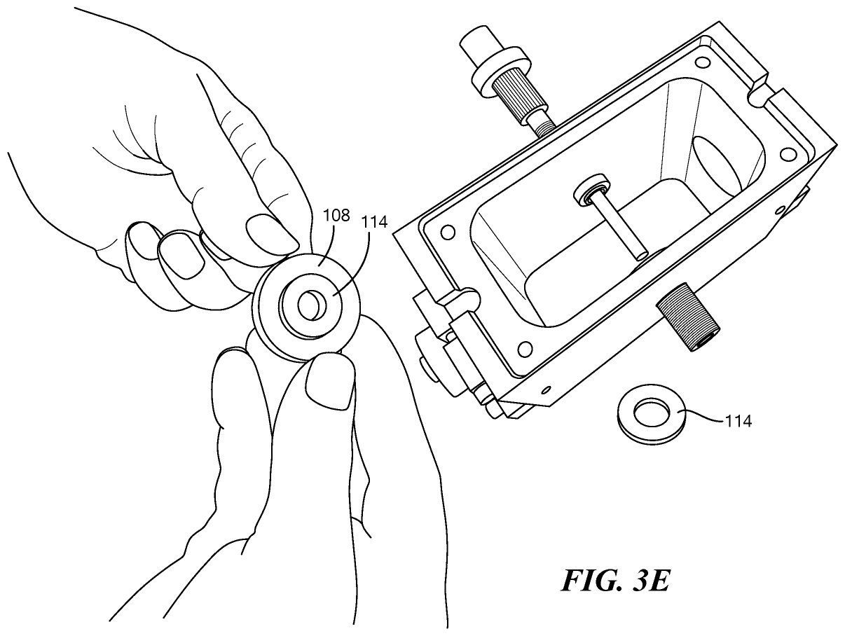

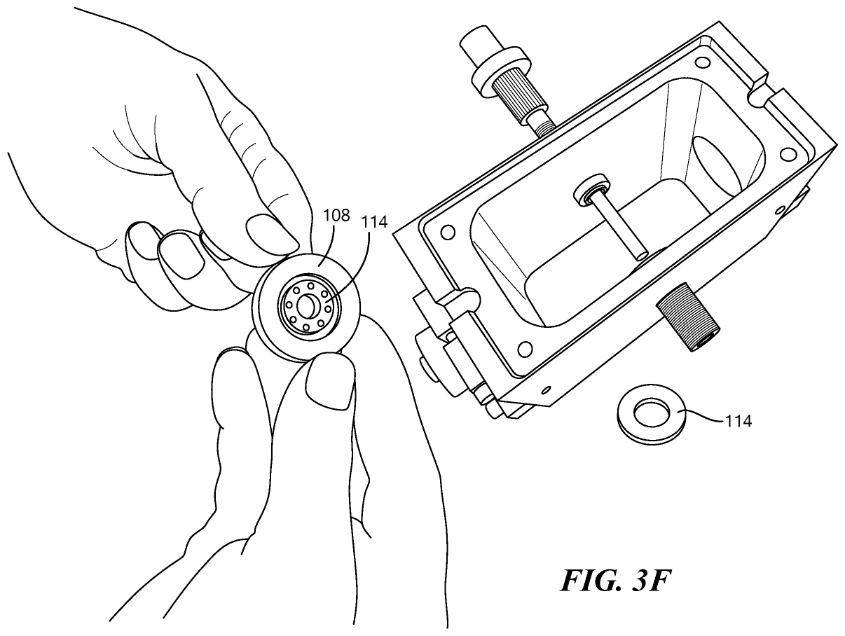

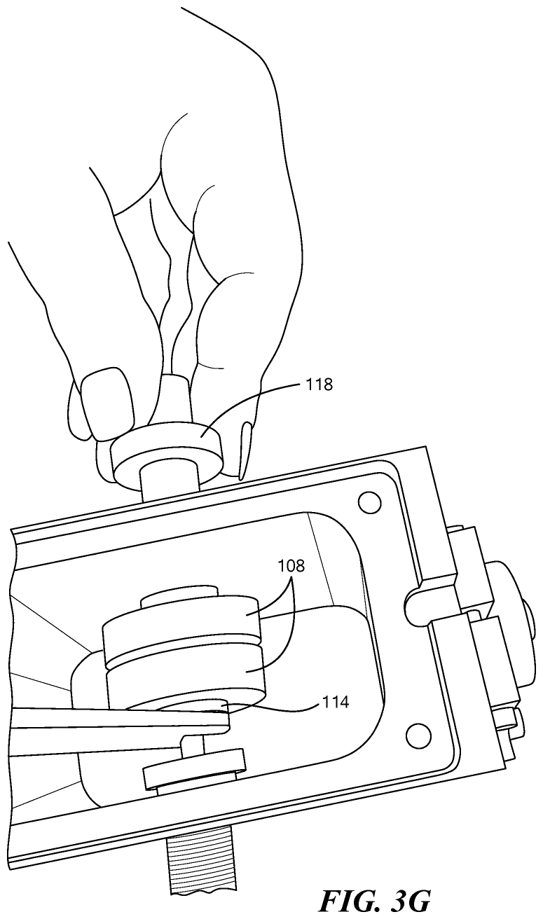

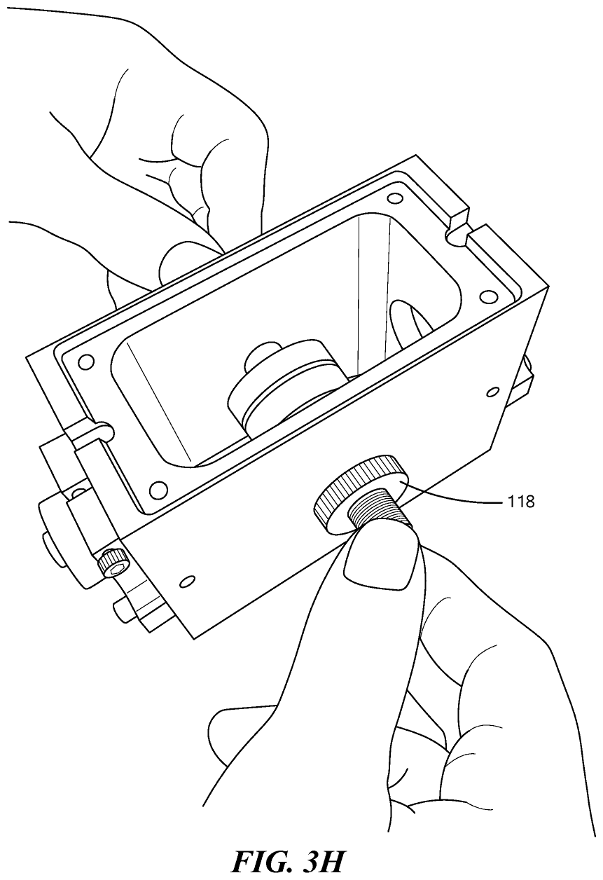

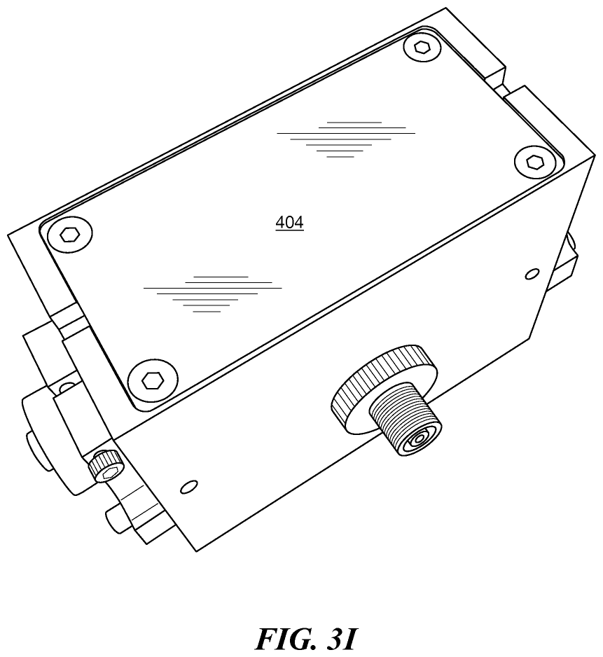

In an embodiment, and with reference still to FIGS. 1 and 2 collectively, each of the first portion 200 and the second portion 300 of apparatus 100 includes: a housing 400 having an internal cavity 402 and a removable cover 404 (best seen with reference to FIGS. 3A and 31), wherein the combination of the housing 400 with the cover 404 attached forms an electromagnetic resonance chamber 406 inside the cavity 402; a container 102 configured to receive the sample of material 500, wherein the container 102 extends along a y-axis of the housing 400 through opposing sidewalls 408, 410 of the housing 400 and passes through an x-y-z center point 412 of the cavity 402; two opposing electrical signal lines 104, 106 oriented along an x-axis of the housing 400 disposed and configured to couple to an electromagnetic resonant mode of the cavity 402 with the sample of material 500, the signal lines 104, 106 being connected to the housing 400 via connectors 116; at least one resonator 108 concentrically disposed about the container 102 and disposed within the cavity 402, wherein the at least one resonator 108 is fixed or fixedly movable relative to the y-axis; and, a frequency tuner 110 concentrically disposed about the container 102 and at least partially disposed within the cavity 402 between the at least one resonator 108 and one of the sidewalls 408, 410 of the housing 400, wherein the frequency tuner 110 is fixedly movable along the y-axis. In an embodiment, the housing 400 and the cover 404 are formed of a non-magnetic metal material, such as but not limited to aluminum, for example.

In an embodiment, and with particular reference now to FIG. 1, the at least one resonator 108 includes first and second dielectric resonator pucks 108.1, 108.2 concentrically disposed about the container 102 and disposed within the cavity 402, wherein the first and second dielectric resonator pucks 108.1, 108.2 are fixedly movable relative to each other along the y-axis, and are separated by a gap 112. In an embodiment, the frequency tuner 110 is a dielectric frequency tuner puck 110 concentrically disposed about the container 102 and disposed within the cavity 402 between one of the first and second dielectric resonator pucks 108.1, 108.2 and a sidewall 408, 410 of the housing 400, wherein the dielectric frequency tuner puck 110 is fixedly movable along the y-axis. In an embodiment, the container 102 and dielectric frequency tuner puck 110 are held in place relative to the housing 400 by locking nuts 118.

In an embodiment, the first and second dielectric resonator pucks 108.1, 108.2 are fixedly moveable relative to each other by means of dielectric retainers 114 that have a controlled degree of freedom of movement along the y-axis. In an embodiment, the dielectric retainers 114 comprise two pairs of nuts 114.1, 114.2, with one nut disposed on each side of respective ones of the first and second dielectric resonator pucks 108.1, 108.2, wherein the nuts 114.1, 114.2 are threadably engaged with the container 102, the container 102 having external threads, and the nuts 114.1, 114.2 having internal threads. In an embodiment, the dielectric frequency tuner puck 110 is also threadably engaged with the container 102, the container 102 having external threads, and the frequency tuner puck 110 having internal threads.

In an embodiment, the first and second dielectric resonator pucks 108.1, 108.2 are formed of a first dielectric material, and the dielectric retainers 114 are formed of a second dielectric material, wherein the first dielectric material has a dielectric constant that is greater than the dielectric constant of the second dielectric material. In an embodiment, the first dielectric material has a dielectric constant equal to or greater than 30, and the second dielectric material has a dielectric constant equal to or less than 4. In an embodiment, the first dielectric material comprises a ceramic. In an embodiment, the second dielectric material comprises a plastic. By employing substantially different dielectric constants for the materials of the first and second dielectric resonator pucks108.1, 108.2, and the dielectric retainers 114, the former being higher than the latter, an enhanced Q-factor (quality factor Q) in the electromagnetic resonance chamber 406 is achievable. In an embodiment, the dielectric frequency tuner puck 110 is also formed of the first dielectric material.

In an embodiment, a given one of the first and second dielectric resonator pucks 108.1, 108.2 is formed of a first volume of material, a given one of the dielectric retainers 114 is formed of a second volume of material, and the dielectric frequency tuner puck 110 is formed of a third volume of material, wherein the first volume of material is greater than the second volume of material, and greater than the third volume of material, and wherein the third volume of material is greater than the second volume of material. In an embodiment, the second volume of material of all of the dielectric retainers 114 combined, is less than 50% of the first volume of material of the first and second dielectric resonator pucks 108.1 108.2, combined. By distinguishing the volumes of materials of the various dielectric components within the electromagnetic resonance chamber 406 as disclosed herein, a further enhanced Q-factor (quality factor Q) in the electromagnetic resonance chamber 406 is achievable.

In an embodiment, and with particular reference now to FIG. 2, the frequency tuner 110 is formed of a metal or a high dielectric constant material, and in an embodiment has a dielectric constant equal to or greater than 30. In an embodiment, the at least one resonator 108 is fixed with no degree of freedom of movement along the y-axis, and has a dielectric constant equal to or greater than 30. In an embodiment, the at least one resonator 108 is a dielectric resonator, or alternatively a metal resonator. In an embodiment, the frequency tuner 110 is threadably engaged with the container 102, and is fixedly moveable by means of a retainer 114 that has a controlled degree of freedom of movement along the y-axis. In an embodiment, the retainer 114 is a nut that is threadably engaged with container 102, the container 102 having external threads, and the nut 114 having internal threads.

In an embodiment, the sample of material 500 is a particular sample that is, without alteration, usable with both the first apparatus 200 and the second apparatus 300.

Reference is now made to FIGS. 3A, 3B, 3C, 3D, 3E, 3F, 3G, 3H, and 3I, which depict, in sequence, assembly steps of an example construct of the first portion 200 of the apparatus 100 of FIG. 1.

In FIG. 3A, all parts of the first portion 200 are depicted prior to assembly, and are enumerated in accordance with FIG. 1.

In FIG. 3B, the connector 116 is installed in preparation of receiving the electrical signal lines 104, 106.

In FIG. 3C, the frequency tuner 110 is installed.

In FIG. 3D, the container 102 is installed, along with.

In FIGS. 3E and 3F, the retainers 114 are installed.

In FIG. 3G, the resonators 108 are installed.

In FIG. 3H, the locking nuts 118 are installed.

In FIG. 3I, the cover 404 is installed.

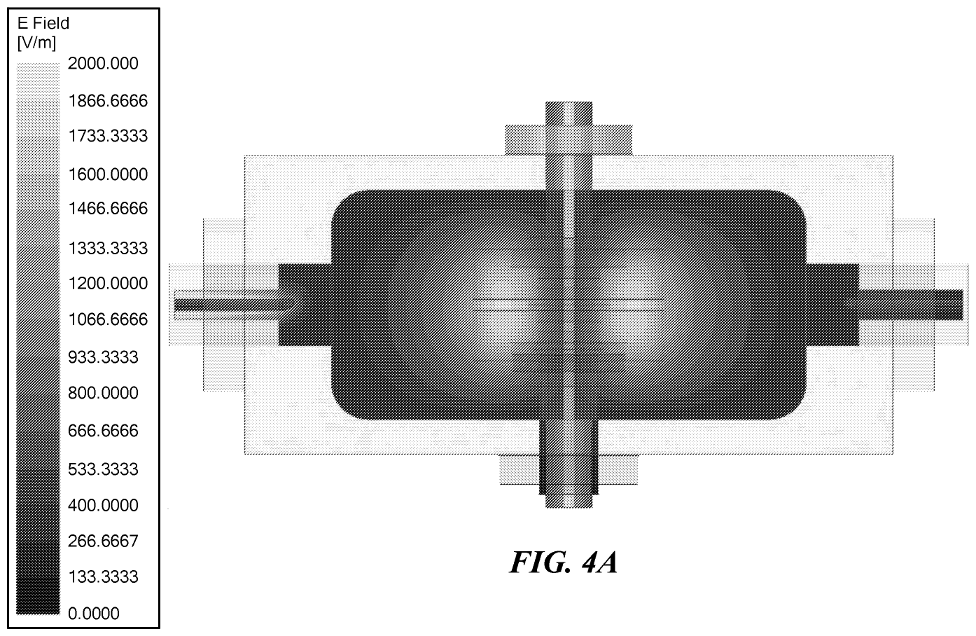

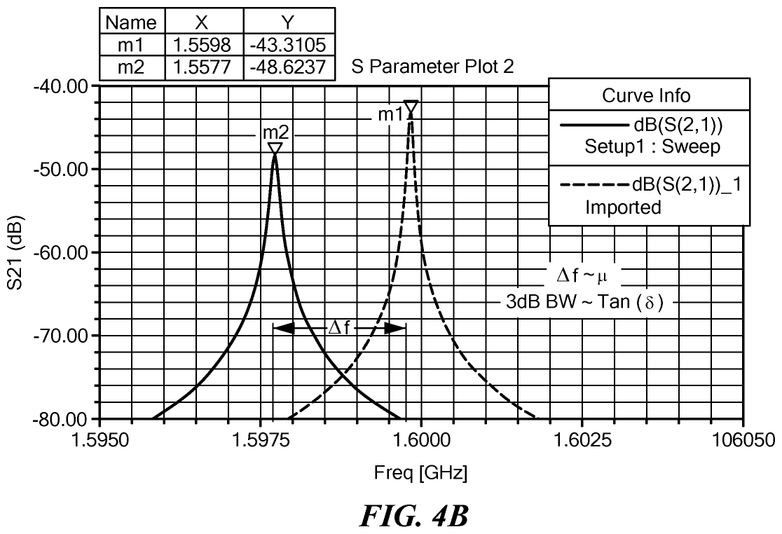

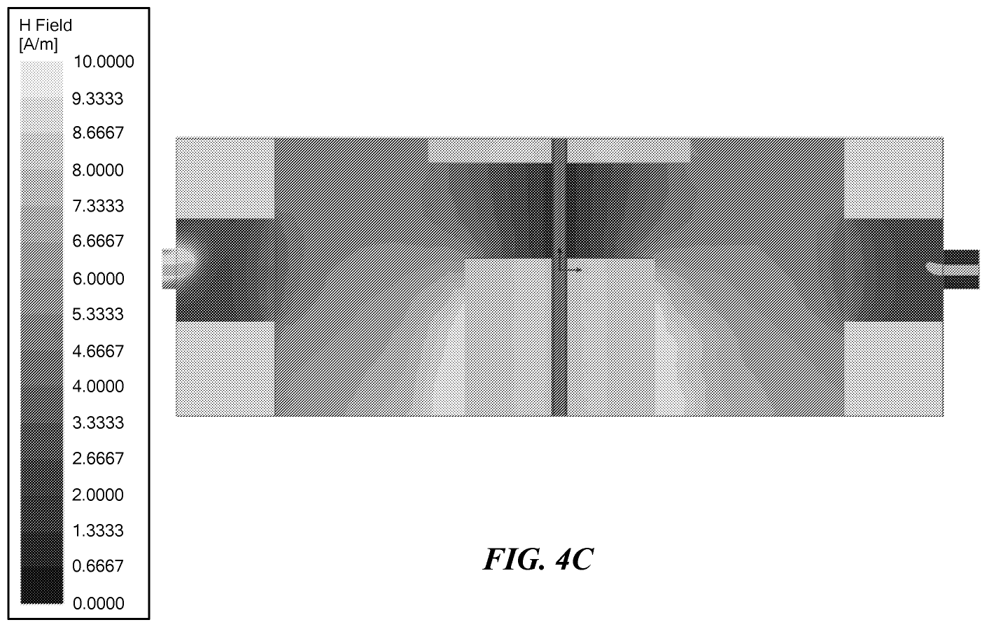

Reference is now made to FIGS. 4A, 4B, and 4C, which depict analytical electromagnetic performance characteristics of the first portion 200 of the apparatus 100 (see FIG. 1) configured to resonate in TE mode with E-field intensity plotted (FIG. 4A), and the second portion 300 of the apparatus 100 (see FIG. 2) configured to resonate in TM mode with H-field intensity plotted (FIG. 4C), where FIG. 4B depicts S(2,1) characteristics of the reconfigurable resonator response depicted in FIG. 4A with (left side plot of FIG. 4B) and without (right side plot of FIG. 4B) the sample of material 500 in situ. In the embodiment depicted in FIG. 4A, the E-field distribution is plotted and shows to be of low intensity in a vicinity very close to and surrounding the sample of material 500. More specifically, the first portion 200 is tuned to produce substantially no E-field at the center 412 of the cavity 402 where the sample of material 500 is positioned. As can be seen from FIG. 4B, a frequency shift occurs in the presence of the sample of material 500 being fully inserted into the container 102 and the apparatus 100 tuned to the resonance frequency of the electromagnetic resonance chamber 406, where the frequency shift, delta-f, is proportional to the permeability, μ, of the sample of material 500. As can also be seen from FIG. 4B, a 3 dB bandwidth, BW, is defined, which defines the magnetic loss tangent, δμ, of the sample of material 500. And while not specifically illustrated, a similar output graph for the second portion 300 of FIG. 4C can be generated to provide test results for the permittivity, ε, and a dielectric loss tangent, δε, of the sample of material 500. With respect to the embodiment depicted in FIG. 4C, the H-field distribution is plotted and shows to be of low intensity in a vicinity close to and surrounding the sample of material 500. More specifically, the second portion 300 is tuned to produce substantially no H-field at the center 412 of the cavity 402 where the sample of material 500 is positioned.

From the foregoing description of the first portion 200 of the apparatus 100, it will be appreciated that a method of measuring magnetic properties of a sample of material 500 includes using the first portion 200 of apparatus 100 as disclosed herein by: inserting the particular sample 500 into the container 102 until it is disposed fully inside the cavity 402 in the container 102; energizing the two opposing electrical signal lines 104, 106 with a particular frequency to cause the first and second dielectric resonator pucks 108.1, 108.2 to resonate; while monitoring signal feedback on the two opposing electrical signal lines 104, 106 via a network analyzer 600, adjusting along the y-axis the gap 112 between the first and second dielectric resonator pucks 108.1, 108.2 to obtain a coarse tuning adjustment, and adjusting along the y-axis the frequency tuner 110 to obtain a fine tuning adjustment, wherein the coarse and fine tuning adjustments result in the first and second resonator pucks 108.1, 108.2, and the particular sample 500, resonating in a TE mode at the resonant mode of the electromagnetic resonance chamber 406; and, measuring at least one of the permeability and the magnetic loss tangent of the particular sample 500 via the signal feedback and the network analyzer 600. In an embodiment, the particular frequency used is 1.6 GHz.

From the foregoing description of the second portion 300 of the apparatus 100, it will be appreciated that a method of measuring electrical properties of a sample of material 500 includes using the second portion 300 of apparatus 100 as disclosed herein by: inserting the particular sample 500 into the container 102 until it is disposed fully inside the cavity 402 in the container 102; energizing the two opposing electrical signal lines 104, 106 with a particular frequency; while monitoring signal feedback on the two opposing electrical signal lines 104, 106 via a network analyzer 600, adjusting along the y-axis a frequency tuned condition, by adjusting along the y-axis the position of the at least one resonator 108, that results in the at least one resonator 108, and the particular sample 500, resonating in a TM mode at the resonant mode of the cavity 402; and, measuring at least one of the permittivity and the dielectric loss tangent of the particular sample 500 via the signal feedback and the network analyzer 600. In an embodiment, the particular frequency used is 1.6 GHz.

While certain combinations of individual features have been described and illustrated herein, it will be appreciated that these certain combinations of features are for illustration purposes only and that any combination of any of such individual features may be employed in accordance with an embodiment, whether or not such combination is explicitly illustrated, and consistent with the disclosure herein. Any and all such combinations of features as disclosed herein are contemplated herein, are considered to be within the understanding of one skilled in the art when considering the application as a whole, and are considered to be within the scope of the invention disclosed herein, as long as they fall within the scope of the invention defined by the appended claims, in a manner that would be understood by one skilled in the art.

While an invention has been described herein with reference to example embodiments, it will be understood by those skilled in the art that various changes may be made and equivalents may be substituted for elements thereof without departing from the scope of the claims. Many modifications may be made to adapt a particular situation or material to the teachings of the invention without departing from the essential scope thereof. Therefore, it is intended that the invention not be limited to the particular embodiment or embodiments disclosed herein as the best or only mode contemplated for carrying out this invention, but that the invention will include all embodiments falling within the scope of the appended claims. In the drawings and the description, there have been disclosed example embodiments and, although specific terms and/or dimensions may have been employed, they are unless otherwise stated used in a generic, exemplary and/or descriptive sense only and not for purposes of limitation, the scope of the claims therefore not being so limited. The use of the terms first, second, etc., or enumerated in the drawings as such, does not denote any order or importance, but rather the terms first, second, etc. are used to distinguish one element from another. The use of the terms a, an, etc. does not denote a limitation of quantity, but rather denotes the presence of at least one of the referenced item. The term “comprising” as used herein does not exclude the possible inclusion of one or more additional features. And, any background information provided herein is provided to reveal information believed by the applicant to be of possible relevance to the invention disclosed herein. No admission is necessarily intended, nor should be construed, that any of such background information constitutes prior art against an embodiment of the invention disclosed herein.

In view of all of the foregoing, it will be appreciated that various aspects of an embodiment are disclosed herein, which are in accordance with, but not limited to, at least the following aspects and/or combinations of aspects.

Aspect 1: An apparatus for measuring at least one electromagnetic property of a sample of material, comprising: a housing having an internal cavity and a removable cover, wherein the combination of the housing with the cover attached forms an electromagnetic resonance chamber; a container configured to receive the sample of material, wherein the container extends along a y-axis of the housing through opposing sidewalls of the housing and passes through an x-y-z center point of the cavity; two opposing electrical signal lines oriented along an x-axis of the housing that are disposed and configured to couple to an electromagnetic resonant mode of the cavity; at least one resonator concentrically disposed about the container and disposed within the cavity, wherein the at least one resonator is fixed or fixedly movable relative to the y-axis; and, a frequency tuner concentrically disposed about the container and at least partially disposed within the cavity between the at least one resonator and one of the sidewalls of the housing, wherein the frequency tuner is fixedly movable along the y-axis.

Aspect 2: The apparatus of Aspect 1, wherein: the at least one resonator is at least one dielectric resonator that is fixedly movable relative to the y-axis.

Aspect 3: The apparatus of Aspect 2, wherein: the at least one electromagnetic property is a magnetic property; the at least one dielectric resonator comprises first and second dielectric resonator pucks concentrically disposed about the container and disposed within the cavity, wherein the first and second dielectric resonator pucks are fixedly movable relative to each other along the y-axis, wherein the first and second dielectric resonator pucks are separated by a gap; wherein the frequency tuner comprises a dielectric frequency tuner puck concentrically disposed about the container and disposed within the cavity between one of the first and second dielectric resonator pucks and a sidewall of the housing; and, wherein the dielectric frequency tuner puck is fixedly movable along the y-axis.

Aspect 4: The apparatus of any one of Aspects 1 to 3, wherein: the at least one electromagnetic property includes permeability and magnetic loss tangent.

Aspect 5: The apparatus of any one of Aspects 1 to 4, wherein: the housing and the cover are formed of a non-magnetic metal material.

Aspect 6: The apparatus of Aspect 5, wherein: the non-magnetic metal material comprises aluminum.

Aspect 7: The apparatus of any one of Aspects 3 to 6, wherein: the first and second dielectric resonator pucks are fixedly moveable by means of dielectric retainers that have a controlled degree of freedom of movement along the y-axis.

Aspect 8: The apparatus of Aspect 7, wherein: the dielectric retainers comprise two pairs of nuts, with one nut disposed on each side of the first and second dielectric resonator pucks, wherein the nuts are threadably engaged with the container.

Aspect 9: The apparatus of any one of Aspects 3 to 8, wherein: the dielectric frequency tuner puck is threadably engaged with the container.

Aspect 10: The apparatus of any one of Aspects 7 to 8, wherein: the first and second dielectric resonator pucks are formed of a first dielectric material; and, the dielectric retainers are formed of a second dielectric material.

Aspect 11: The apparatus of Aspect 10, wherein: the first dielectric material has a dielectric constant that is greater than the dielectric constant of the second dielectric material.

Aspect 12: The apparatus of any one of Aspects 10 to 11, wherein: the first dielectric material has a dielectric constant equal to or greater than 30.

Aspect 13: The apparatus of any one of Aspect 10 to 12, wherein: the first dielectric material comprises a ceramic.

Aspect 14: The apparatus of any one of Aspects 10 to 13, wherein: the second dielectric material has a dielectric constant equal to or less than 4.

Aspect 15: The apparatus of any one of Aspect 10 to 14, wherein: the second dielectric material comprises a plastic.

Aspect 16: The apparatus of any one of Aspects 10 to 15, wherein: the dielectric frequency tuner puck is formed of the first dielectric material.

Aspect 17: The apparatus of any one of Aspects 7 to 16, wherein: a given one of the first and second dielectric resonator pucks is formed of a first volume of material; a given one of the dielectric retainers is formed of a second volume of material; the dielectric frequency tuner puck is formed of a third volume of material; the first volume of material is greater than the second volume of material, and greater than the third volume of material; and, the third volume of material is greater than the second volume of material.

Aspect 18: The apparatus of Aspect 17, wherein: the second volume of material of all of the dielectric retainers combined is less than 50% of the first volume of material of first and second dielectric resonator pucks combined.

Aspect 19: The apparatus of any one of Aspects 1 to 18, wherein: the sample of material is a solid, a powder, or a liquid.

Aspect 20: The apparatus of Aspect 1, wherein: the at least one electromagnetic property is an electrical property; and, the frequency tuner is formed of a metal or a high dielectric constant material.

Aspect 21: The apparatus of Aspect 20, wherein: the frequency tuner is formed of the high dielectric constant material having a dielectric constant equal to or greater than 30.

Aspect 22: The apparatus of any one of Aspects 1 and 20 to 21, wherein: the at least one electromagnetic property includes permittivity and dielectric loss tangent.

Aspect 23: The apparatus of any one of Aspects 20 to 22, wherein: the housing and the cover are formed of a non-magnetic metal material.

Aspect 24: The apparatus of Aspect 23, wherein: the non-magnetic metal material comprises aluminum.

Aspect 25: The apparatus of any one of Aspects 1 and 20 to 24, wherein: the at least one resonator is fixed with no degree of freedom of movement along the y-axis.

Aspect 26: The apparatus of any one of Aspects 1 and 20 to 25, wherein: the frequency tuner is threadably engaged with the container.

Aspect 27: The apparatus of any one of Aspects 1 and 20 to 26, wherein: the at least one resonator has a dielectric constant equal to or greater than 30.

Aspect 28: The apparatus of any one of Aspects 1 and 20 to 27, wherein: the frequency tuner is fixedly moveable by means of a retainer that has a controlled degree of freedom of movement along the y-axis

Aspect 29: The apparatus of Aspect 28, wherein: the retainer comprises a nut that is threadably engaged with container.

Aspect 30: The apparatus of any one of Aspects 20 to 29, wherein: the sample of material is a solid, a powder, or a liquid.

Aspect 31: The apparatus of any one of Aspects 1 to 30, wherein: the sample of material is a particular sample that is usable with the apparatus of Aspects 1 to 30.

Aspect 32: A method of measuring magnetic properties of a sample of material, the method comprising: using the apparatus of any one of Aspects 3 to 19: inserting the particular sample of Aspect 31 into the container until it is disposed fully inside the cavity in the container; energizing the two opposing electrical signal lines with a particular frequency to cause the first and second dielectric resonator pucks to resonate; while monitoring signal feedback on the two opposing electrical signal lines via a network analyzer, adjusting along the y-axis the gap between the first and second dielectric resonator pucks to obtain a coarse tuning adjustment, and adjusting along the y-axis the frequency tuner to obtain a fine tuning adjustment, wherein the coarse and fine tuning adjustments result in the first and second resonator pucks, and the particular sample, resonating in a TE mode at the resonant mode of the cavity; and, measuring at least one of the permeability and the magnetic loss tangent of the particular sample via the signal feedback and the network analyzer.

Aspect 33: The method of Aspect 32, wherein: the particular frequency is 1.6 GHz.

Aspect 34: A method of measuring electric properties of a sample of material, the method comprising: using the apparatus of any one of Aspects 20 to 30: inserting the particular sample of Aspect 31 into the container until it is disposed fully inside the cavity in the container; energizing the two opposing electrical signal lines with a particular frequency; while monitoring signal feedback on the two opposing electrical signal lines via a network analyzer, adjusting along the y-axis a frequency tuned condition, by adjusting along the y-axis the position of the at least one resonator, that results in the at least one resonator, and the particular sample, resonating in a TM mode at the resonant mode of the cavity; and, measuring at least one of the permittivity and the dielectric loss tangent of the particular sample via the signal feedback and the network analyzer.

Aspect 35: The method of Aspect 34, wherein: the particular frequency is 1.6 GHz.

1. An apparatus for measuring at least one electromagnetic property of a sample of material, comprising:
a housing having an internal cavity and a removable cover, wherein the combination of the housing with the cover attached forms an electromagnetic resonance chamber;
a container configured to receive the sample of material, wherein the container extends along a y-axis of the housing through opposing sidewalls of the housing and passes through an x-y-z center point of the cavity;
two opposing electrical signal lines oriented along an x-axis of the housing that are disposed and configured to couple to an electromagnetic resonant mode of the cavity;
at least one resonator concentrically disposed about the container and disposed within the cavity, wherein the at least one resonator is fixed or fixedly movable relative to the y-axis; and
a frequency tuner concentrically disposed about the container and at least partially disposed within the cavity between the at least one resonator and one of the sidewalls of the housing, wherein the frequency tuner is fixedly movable along the y-axis.

2. The apparatus of claim 1, wherein:
the at least one resonator is at least one dielectric resonator that is fixedly movable relative to the y-axis.

3. The apparatus of claim 2, wherein:
the at least one electromagnetic property is a magnetic property;
the at least one dielectric resonator comprises first and second dielectric resonator pucks concentrically disposed about the container and disposed within the cavity, wherein the first and second dielectric resonator pucks are fixedly movable relative to each other along the y-axis, wherein the first and second dielectric resonator pucks are separated by a gap;
the frequency tuner comprises a dielectric frequency tuner puck concentrically disposed about the container and disposed within the cavity between one of the first and second dielectric resonator pucks and a sidewall of the housing, wherein the dielectric frequency tuner puck is fixedly movable along the y-axis.

4. The apparatus of claim 1, wherein:
the at least one electromagnetic property includes permeability and magnetic loss tangent.

5. The apparatus of claim 3, wherein:
the first and second dielectric resonator pucks are fixedly moveable by means of dielectric retainers that have a controlled degree of freedom of movement along the y-axis.

6. The apparatus of claim 5, wherein:
the dielectric retainers comprise two pairs of nuts, with one nut disposed on each side of the first and second dielectric resonator pucks, wherein the nuts are threadably engaged with the container.

7. The apparatus of claim 3, wherein:
the dielectric frequency tuner puck is threadably engaged with the container.

8. The apparatus of claim 5, wherein:
the first and second dielectric resonator pucks are formed of a first dielectric material; and
the dielectric retainers are formed of a second dielectric material.

9. The apparatus of claim 8, wherein:
the first dielectric material has a dielectric constant that is greater than the dielectric constant of the second dielectric material.

10. The apparatus of claim 10, wherein:
the dielectric frequency tuner puck is formed of the first dielectric material.

11. The apparatus of claim 5, wherein:
a given one of the first and second dielectric resonator pucks is formed of a first volume of material;
a given one of the dielectric retainers is formed of a second volume of material;
the dielectric frequency tuner puck is formed of a third volume of material;
the first volume of material is greater than the second volume of material, and greater than the third volume of material;
the third volume of material is greater than the second volume of material.

12. The apparatus of claim 11, wherein:
the second volume of material of all of the dielectric retainers combined is less than 50% of the first volume of material of first and second dielectric resonator pucks combined.

13. The apparatus of claim 1, wherein:
the at least one electromagnetic property is an electrical property;
the frequency tuner is formed of a metal or a high dielectric constant material.

14. The apparatus of claim 1, wherein:
the at least one electromagnetic property includes permittivity and dielectric loss tangent.

15. The apparatus of claim 1, wherein:
the at least one resonator is fixed with no degree of freedom of movement along the y-axis.

16. The apparatus of claim 1, wherein:
the frequency tuner is threadably engaged with the container.

17. The apparatus of claim 1, wherein:
the frequency tuner is fixedly moveable by means of a retainer that has a controlled degree of freedom of movement along the y-axis

18. The apparatus of claim 1, wherein:
the sample of material is a particular sample that is usable with the apparatus of both claim 3 and claim 13.

19. A method of measuring magnetic properties of a sample of material, the method comprising:
using the apparatus of claim 3:
inserting the sample of material into the container until it is disposed fully inside the cavity in the container;
energizing the two opposing electrical signal lines with a particular frequency to cause the first and second dielectric resonator pucks to resonate;
while monitoring signal feedback on the two opposing electrical signal lines via a network analyzer, adjusting along the y-axis the gap between the first and second dielectric resonator pucks to obtain a coarse tuning adjustment, and adjusting along the y-axis the frequency tuner to obtain a fine tuning adjustment, wherein the coarse and fine tuning adjustments result in the first and second resonator pucks, and the particular sample, resonating in a TE mode at the resonant mode of the cavity; and
measuring at least one of the permeability and the magnetic loss tangent of the particular sample via the signal feedback and the network analyzer.

20. A method of measuring electric properties of a sample of material, the method comprising:
inserting the apparatus of claim 13:
inserting the sample of material into the container until it is disposed fully inside the cavity in the container;
energizing the two opposing electrical signal lines with a particular frequency;
while monitoring signal feedback on the two opposing electrical signal lines via a network analyzer, adjusting along the y-axis a frequency tuned condition, by adjusting along the y-axis the position of the at least one resonator, that results in the at least one resonator, and the particular sample, resonating in a TM mode at the resonant mode of the cavity; and
measuring at least one of the permittivity and the dielectric loss tangent of the particular sample via the signal feedback and the network analyzer.
